(19) United States
(12) Patent Application Publication
(10) Pub. No.: US 2024/0222566 A1
(43) Pub. Date: Jul. 4, 2024

(54) OPTOELECTRONIC SEMICONDUCTOR DEVICE

(71) Applicant: UNIKORN SEMICONDUCTOR CORPORATION, Hsinchu (TW)

(72) Inventors: Tzu-Ling Yang, Hsinchu (TW); Ching-En Huang, Hsinchu (TW); Hao-Ming Ku, Hsinchu (TW); Shih-I Chen, Hsinchu (TW); Chien-Jun Wei, Hsinchu (TW); Ya-Wen Lin, Hsinchu (TW); Chuang-Sheng Lin, Hsinchu (TW)

(21) Appl. No.: 18/403,278

(22) Filed: Jan. 3, 2024

(30) Foreign Application Priority Data
Jan. 4, 2023 (TW) 112200043

(51) Int. Cl. H01L 33/44; H01L 33/24

(52) U.S. Cl. CPC H01L 33/44; H01L 33/24

(57) ABSTRACT

An optoelectronic semiconductor device is provided. The optoelectronic semiconductor device includes a stack structure having a top surface and including a first semiconductor layer, a second semiconductor layer and an active region between the first semiconductor layer and the second semiconductor layer. The optoelectronic semiconductor device further includes a first insulating structure covering the stack structure and having a first upper surface and a sidewall. The first upper surface is coplanar with or lower than the top surface of the stack structure. The optoelectronic semiconductor device further includes a second insulating structure covering the first upper surface, the sidewall of the first insulating structure and the top surface of the stack structure. The first insulating structure directly contacts the second insulating structure.

### CROSS-REFERENCE TO RELATED APPLICATIONS

The present application claims priority of Taiwan Application No. 112200043, filed on Jan. 4, 2023, which is incorporated by reference herein in its entirety.

### BACKGROUND

### Technical Field

The present disclosure relates to semiconductor devices, and more particularly to optoelectronic semiconductor devices.

### Description of the Related Art

Semiconductor elements are widely used, and the research and development of related materials are also continuously being carried out. For example, III-V semiconductor materials containing group III and group V elements may be applied to various optoelectronic semiconductor elements, such as light-emitting devices (for example, light-emitting diodes or laser diodes), light-absorbing devices (for example, photodetectors or solar cells) or non-luminous devices (for example, power components of switches or rectifiers), which can be used in lighting, medical treatment, display, communication, sensing, power supply systems and other applications.

Advancements in technology have allowed optoelectronic semiconductor devices to be miniaturized. In recent years, people pay more attention to light-emitting diodes (LEDs) for applications in display devices. Compared with organic light-emitting diode (OLED) display devices, light-emitting diode display devices are more power-saving and more reliable, have a longer lifetime, and exhibit better contrast performance. Furthermore, they provide visibility under sunlight. With the development of technology, the need for development is still required for optoelectronic semiconductor devices. Although existing optoelectronic semiconductor devices have generally met requirements, they are not satisfactory in all respects, and further improvements are still needed.

### SUMMARY

Some embodiments of the present disclosure provide an optoelectronic semiconductor device. The optoelectronic semiconductor device includes a stack structure having a top surface and including a first semiconductor layer, a second semiconductor layer and an active region between the first semiconductor layer and the second semiconductor layer. The optoelectronic semiconductor device further includes a first insulating structure covering the stack structure and having a first upper surface and a sidewall. The first upper surface is coplanar with or lower than the top surface of the stack structure. The optoelectronic semiconductor device further includes a second insulating structure covering the first upper surface, the sidewall of the first insulating structure and the top surface of the stack structure. The first insulating structure directly contacts the second insulating structure.

### BRIEF DESCRIPTION OF THE DRAWINGS

Embodiments of the present disclosure can be best understood from the following detailed description in conjunction with the accompanying drawings. It should be noted that, in accordance with the common practice in the industry, various features are not drawn to scale. In fact, the dimensions of the various elements may be arbitrarily increased or reduced to clearly illustrate the features of the embodiments of the present disclosure.

FIG. 1A illustrates a top view of an optoelectronic semiconductor device according to some embodiments of the present disclosure.

FIGS. 1B and 1C illustrate cross-sectional views of the optoelectronic semiconductor device along line A-A′ shown in FIG. 1A according to some embodiments of the present disclosure.

FIG. 2A illustrates a top view of an optoelectronic semiconductor device according to some embodiments of the present disclosure.

FIG. 2B illustrates a cross-sectional view of the optoelectronic semiconductor device along line A-A′ shown in FIG. 2A according to some embodiments of the present disclosure.

FIG. 3 illustrates a cross-sectional view of an optoelectronic semiconductor device according to some embodiments of the present disclosure.

FIG. 4 illustrates a cross-sectional view of an optoelectronic semiconductor device according to some embodiments of the present disclosure.

FIG. 5A illustrates a top view of an optoelectronic semiconductor device according to some embodiments of the present disclosure.

FIG. 5B illustrates a cross-sectional view of the optoelectronic semiconductor device along line B-B′ shown in FIG. 5A according to some embodiments of the present disclosure.

### DETAILED DESCRIPTION

The following disclosure provides many different embodiments, or examples, for implementing different features of the described subject matter. Specific examples of elements and arrangements are described below to simplify the present description. These are, of course, merely examples and are not intended to be limiting. For example, dimensions of elements are not limited to the disclosed ranges or values, but may depend on process conditions and/or desired characteristics of devices. Further. the formation of a first feature over or on a second feature in the description that follows may include embodiments in which the first and second features are formed in direct contact, and may also include embodiments in which additional features may be formed between the first and second features, such that the first and second features may not be in direct contact. Furthermore, the present disclosure may repeat reference numerals and/or letters in the various examples. This repetition is for the purpose of simplicity and clarity and does not in itself dictate a relationship between the various embodiments and/or configurations discussed.

In the drawings, various elements can be drawn arbitrarily in different scales. The size, shape, or thickness of some of elements may be exaggerated and not drawn to scale, for illustrative purposes. Parts of each element in the drawings will be described separately. It should be noted that elements not shown or described are forms known to those skilled in the art. The disclosure will be described with respect to particular embodiments and with reference to certain drawings, but the disclosure is not limited thereto.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Furthermore, the use of ordinal terms such as “first”, “second”, and “third” in the disclosure to modify an element does not by itself connote any priority, precedence, or order of one claim element over another or the temporal order in which it is formed, but are used merely as labels to distinguish one claim element having a certain name from another element having the same name (but for use of the ordinal term) to distinguish the claim elements.

The composition, the dopant and the defect of each layer of the optoelectronic semiconductor devices in the present disclosure may be analyzed by any suitable method, for example, a secondary ion mass spectrometer (SIMS), a transmission electron microscopy (TEM), or a scanning electron microscopy (SEM). The thickness of each layer may also be analyzed by any suitable method, for example, the transmission electron microscopy (TEM) or the scanning electron microscopy (SEM).

In general, in manufacturing processes of optoelectronic semiconductor devices, such as micro light-emitting diodes (micro LEDs), after an etching process is performed to define a mesa of a stack structure, the sidewalls and top surfaces of optoelectronic semiconductor devices are exposed. The exposed sidewalls and top surfaces of the optoelectronic semiconductor devices are easily damaged by the following etching step during the manufacturing processes, thereby generating sidewall defects or top surface defects. Due to the small sizes of the micro light-emitting diodes, the ratio of the area of the sidewall to the area of the device is relatively large. Therefore, compared with conventional light-emitting diodes having large sizes, the above-mentioned defects have a greater impact on the micro LEDs, which can easily lead to problems such as the failure of photoelectric character, poor reliability, or reduced reverse voltage of the devices, thereby decreasing the production yield.

According to some embodiments of the present disclosure, an insulating structure is provided on entire sidewalls or a portion of sidewalls of a stack structure of an optoelectronic semiconductor device, which can avoid defects on the sidewalls or top surfaces of the optoelectronic semiconductor device due to processing damage, and can increase the reverse voltage, the reliability, and production yield of the optoelectronic semiconductor device.

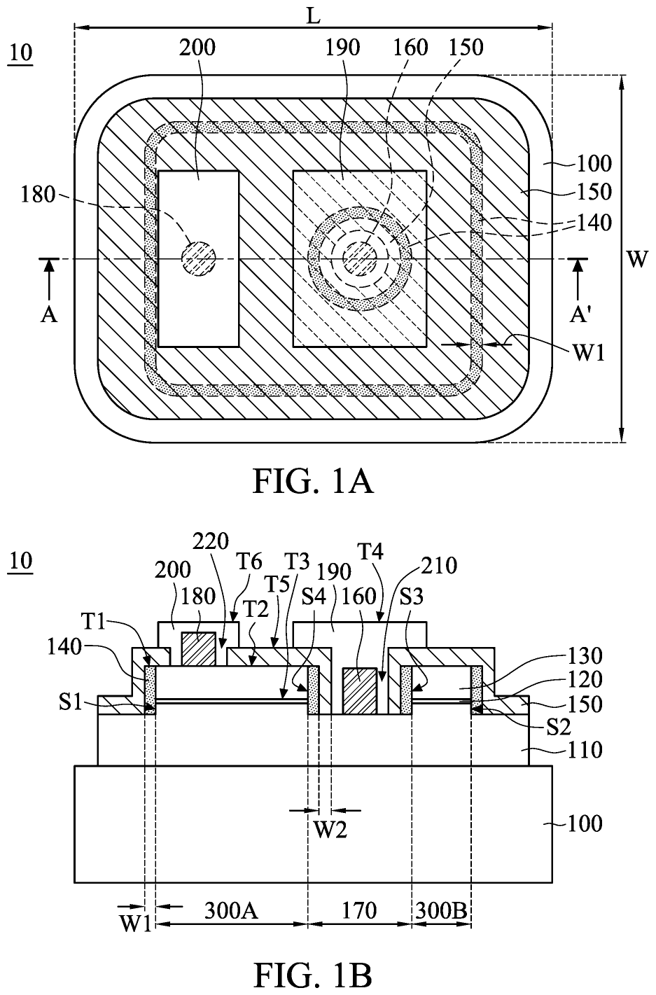

FIG. 1A illustrates a top view of the optoelectronic semiconductor device 10. In some embodiments, the optoelectronic semiconductor device 10 may be a micro light-emitting diode. The optoelectronic semiconductor device 10 has a length L and a width W. In some embodiments, the length L is not greater than 150 μm, such as 20 μm to 150 μm, 20 μm to 60 μm, or 60 μm to 150 μm. The width W is not greater than 100 μm, such as 10 μm to 100 μm, 10 μm to 30 μm, 30 μm to 75 μm, or 75 μm to 100 μm.

FIG. 1B illustrates a cross-sectional view of the optoelectronic semiconductor device 10 along line A-A′ shown in FIG. 1A. As shown in FIG. 1B, the optoelectronic semiconductor device 10 includes a substrate 100 and a stack structure on the substrate 100. The stack structure includes a first semiconductor layer 110, a second semiconductor layer 130 on the first semiconductor layer 110, and an active region 120 between the first semiconductor layer 110 and the second semiconductor layer 130.

In some embodiments, the substrate 100 may include silicon (Si), sapphire, silicon carbide (SiC), gallium arsenide (GaAs), gallium nitride (GaN), aluminum nitride (AlN), aluminum gallium nitride (AlGaN), glass, ceramic, epoxy, quartz or acrylic resin. In an embodiment, the substrate 100 is a sapphire substrate. In addition, the present disclosure uses rectangle as an example of the shape of the substrate 100, but it is not intended to limit the present disclosure. In some embodiments, the shape of the substrate 100 may include a circle, a square, a diamond, or another polygon.

In some embodiments, the first semiconductor layer 110, the active region 120, and the second semiconductor layer 130 may include III-V semiconductor materials, such as compounds of aluminum (Al), gallium (Ga), arsenic (As), phosphorus (P), indium (In) and/or nitrogen (N). In particular, in some embodiments, the above-mentioned III-V semiconductor materials may be binary compound semiconductors (for example, GaAs, GaP, GaN, or InP), ternary compound semiconductors (for example, InGaAs, AlGaAs, GaInP, AlInP, InGaN, or AlGaN), or quaternary compound semiconductors (for example, AlGaInAs, AlGaInP, AlInGaN, InGaAsP, InGaAsN, or AlGaAsP).

In some embodiments, the doping of the first semiconductor layer 110 and the second semiconductor layer 130 may be conducted by in-situ doping during epitaxial growth and/or by implanting using dopants after epitaxial growth. The first semiconductor layer 110 may include a first dopant to have a first conductive type, and the second semiconductor layer 130 may include a second dopant to have a second conductive type. The first semiconductor layer 110 and the second semiconductor layer 130 may have different conductive types. For example, the first conductive type may be p-type and the second conductive type may be n-type to provide holes and electrons, respectively. Alternatively, the first conductive type may be n-type and the second conductive type may be p-type to provide electrons and holes, respectively. In some embodiments, the first dopant or the second dopant may be magnesium (Mg), zinc (Zn), silicon (Si), carbon (C), or tellurium (Te).

In some embodiments, the active region 120 may include a multi-quantum wells (MQWs) structure. The active region 120 can emit light when operating the optoelectronic semiconductor device 10. The light emitted by the active region 120 includes visible light or invisible light. The wavelength of the light emitted by the optoelectronic semiconductor device 10 depends on the composition of the material of the active region 120. For example, when the material of the active region 120 includes InGaN, the active region 120 can emit blue light or deep blue light with a peak wavelength of 400 nm to 490 nm, or the active region 120 can emit green light with a peak wavelength of 490 nm to 550 nm. When the material of the active region 120 includes AlGaN or AlGaInN material, the active region 120 can emit ultraviolet light with a peak wavelength of 250 nm to 400 nm. When the material of the active region 120 includes InGaAs, InGaAsP, AlGaAs, or AlGaInAs material, the active region 120 can emit infrared light with a peak wavelength of 700 nm to 1700 nm. When the material of the active region 120 includes InGaP or AlGaInP material, the active region 120 can emit red light with a peak wavelength of 610 nm to 700 nm, or the active region 120 can emit yellow light with a peak wavelength of 530 nm to 600 nm.

In some embodiments, when forming the optoelectronic semiconductor device 10, the stack structure may be formed on another growth substrate (not shown) by an epitaxial growth process, such as metal-organic chemical vapor deposition (MOCVD), hydride vapor phase epitaxy (HVPE), molecular beam epitaxy (MBE), liquid phase epitaxy (LPE), vapor phase epitaxy (VPE), or other epitaxial growth processes. The growth substrate is inverted and bonded to the substrate 100, and then the growth substrate is removed. A bonding material can be provided between the stack structure and the substrate to enhance the bonding strength. The bonding material can be light-transmitting materials, such as light-transmitting glue. In other embodiments, the substrate 100 may be a growth substrate, and the stack structure may be directly and epitaxially grown on the substrate 100. Therefore, in various embodiments of the present disclosure, the upper and lower positions of elements in various schematic diagrams are not intended to limit their forming sequence.

Referring to FIGS. 1A and 1B, the stack structure includes mesa portions 300A, 300B and recess 170 located between the mesa portions 300A and 300B. From top view of the optoelectronic semiconductor device 10, the mesa portion 300A includes an outer sidewall S1 and an inner sidewall S4, and the mesa portion 300B includes an outer sidewall S2 and an inner sidewall S3. The outer sidewalls S1 and S2 of the mesa portions 300A and 300B surround the inner sidewalls S3 and S4 of the mesa portions 300A and 300B. The inner sidewalls S3 and S4 of the mesa portions 300A and 300B define recess 170. In some embodiments, the mesa portions 300A, 300B and the recess 170 may be formed by removing portions of the stack structure through an etching process. In some embodiments, the etching process may be a dry etching process, a wet etching process, or a combination thereof. For example, the dry etching process may include plasma etching (PE), reactive ion etching (RIE), and inductively coupled plasma reactive ion etching (ICP-RIE). The wet etching process may use acidic solution or alkaline solution.

Referring to FIG. 1B, the optoelectronic semiconductor device 10 includes a first insulating structure 140 disposed on the inner sidewalls S3 and S4 or/and the outer sidewalls S1 and S2 of the mesa portions 300A and 300B. The first insulating structure 140 includes a first upper surface T1, the stack structure includes a top surface T2, and the active region 120 includes a second upper surface T3. In some embodiments, the first upper surface T1 of the first insulating structure 140 is coplanar with the top surface T2 of the stack structure. In other embodiments, the first upper surface T1 of the first insulating structure 140 is lower than the top surface T2 of the stack structure and higher than the second upper surface T3 of the active region 120. In other words, the first insulating structure 140 does not cover the top surface T2 of the stack structure. In some embodiments, the top surface T2 of the stack structure is the top surface of the second semiconductor layer 130. In an embodiment, the first insulating structure 140 covers the sidewall of the active region 120 to protect the active region 120, thereby improving the reliability of the optoelectronic semiconductor device 10. In the embodiment shown in FIG. 1B, although the first insulating structure 140 is rectangular, the first insulating structure 140 may include a shape other than a rectangle, such as a triangle, another polygon, or combinations thereof.

In general, current leakage paths are easily formed on the exposed sidewalls of a bipolar junction (for example, PN junction) in the device (for example, light-emitting diode). Once the leakage current generated, the reliability of the device deteriorates. According to some embodiments of the present disclosure, forming the first insulating structure 140 on the sidewalls of the stack structure can avoid the failure of the optoelectronic semiconductor device 10 caused by leakage, and can increase the reverse voltage of the optoelectronic semiconductor device 10, thereby improving the reliability and yield of the optoelectronic semiconductor device 10.

If the first upper surface T1 of the first insulating structure 140 is lower than the second upper surface T3 of the active region 120, that is, the first insulating structure 140 cannot cover the sidewall of the active region 120, and the negative impact of leakage cannot be prevented. If the first upper surface T1 of the first insulating structure 140 is higher than the top surface T2 of the stack structure, it may become more difficult to form subsequent components, or need to conduct additional processes (for example, chemical mechanical planarization), which increases processing costs.

The first insulating structure 140 includes a first thickness W1. In some embodiments, the first thickness W1 of the first insulating structure 140 may be 10 Å to 3 μm, such as 10 Å to 3000 Å. If the first thickness W1 is less than 10 Å, the first insulating structure 140 may be too thin to reduce the leakage. If the first thickness W1 is greater than 3 μm, the first insulating structure 140 may be too thick to provide significant benefits. More specifically, when the first thickness W1 is greater than 3 μm, the manufacturing costs increases and the size of the optoelectronic semiconductor device 10 becomes bigger.

In some embodiments, the first insulating structure 140 may include an oxide insulating material, a non-oxide insulating material, or a combination thereof. For example, the oxide insulating material may include silicon oxide (SiOₓ), titanium oxide (TiOₓ), aluminum oxide (Al₂O₃), tantalum oxide (Ta₂O₅). The non-oxide insulating material may include silicon nitride (SiNₓ), benzocyclobutene (BCB), cycloolefin copolymer (COC), fluorocarbon polymer, calcium fluoride (CaF₂) or magnesium fluoride (MgF₂).

Referring to FIG. 1B, the optoelectronic semiconductor device 10 includes a second insulating structure 150. The second insulating structure 150 covers the first upper surface T1 of the first insulating structure 140 and the sidewall of the first insulating structure 140 and the top surface T2 of the stack structure. The second insulating structure 150 directly contacts the first insulating structure 140. In some embodiments, the material of the second insulating structure 150 may be different from the material of the first insulating structure 140. In other embodiments, the material of the second insulating structure 150 may be the same as that of the first insulating structure 140. For example, the second insulating structure 150 may include an oxide insulating material, a non-oxide insulating material, or a combination thereof. For example, the oxide insulating material may include silicon oxide (SiOₓ), titanium oxide (TiOₓ), aluminum oxide (Al₂O₃), tantalum oxide (Ta₂O₅). The non-oxide insulating material may include silicon nitride (SiNₓ), benzocyclobutene (BCB), cycloolefin copolymer (COC), fluorocarbon polymer, calcium fluoride (CaF₂) or magnesium fluoride (MgF₂).

As shown in FIG. 1B, the second insulating structure 150 includes a first opening 210 on the first semiconductor layer 110 and a second opening 220 on the second semiconductor layer 130. The first opening 210 overlaps the recess 170 in a vertical direction, and the second opening 220 overlaps the mesa portion 300A in the vertical direction. The second opening 220 and the first opening 210 are separated from each other.

Referring to FIG. 1B, the optoelectronic semiconductor component 10 further includes a first electrode 190 and a second electrode 200. The first electrode 190 includes a third upper surface T4, the second insulating structure 150 includes a fourth upper surface T5, and the second electrode 200 includes a fifth upper surface T6. The first electrode 190 fills the first opening 210, and the third upper surface T4 of the first electrode 190 is higher than the fourth upper surface T5 of the second insulating structure 150. The second electrode 200 fills the second opening 220, and the fifth upper surface T6 of the second electrode 200 is higher than the fourth upper surface T5 of the second insulating structure 150. In some embodiments, the third upper surface T4 of the first electrode 190 may be substantially coplanar with the fifth upper surface T6 of the second electrode 200. The first electrode 190 and the second electrode 200 may be used to electrically connect the optoelectronic semiconductor device 10 with an external power source. A current can be conducted in the optoelectronic semiconductor device 10 through the first electrode 190 and the second electrode 200, and drive carriers (electrons and holes) to combine in the stack structure to emit light. The light may be emitted toward the direction of the substrate 100 or away from the substrate 100.

In some embodiments, the material of the first electrode 190 and the material of the second electrode 200 may be the same or different, and each may include metal oxide, metal, or alloy. For example, the metal oxide may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). For example, the metal may include germanium (Ge), beryllium (Be), zinc (Zn), gold (Au), silver (Ag), platinum (Pt), titanium (Ti), aluminum (Al), nickel (Ni), tin (Sn), indium (In), or copper (Cu). For example, the alloy may include at least two metals, such as gold-tin (AuSn), tin-silver-copper (SnAgCu), germanium-gold-nickel (GeAuNi), beryllium-gold (BeAu), germanium-gold (GeAu), zinc gold (ZnAu), or other alloys containing tin (Sn) element.

In some embodiments, the first electrode 190 and the second electrode 200 may be formed by a deposition process. In addition, a planarization process (for example, a chemical mechanical planarization (CMP) process) may be performed so that the third upper surface T4 of the first electrode 190 is substantially coplanar with the fifth upper surface T6 of the second electrode 200. The flat surfaces are beneficial for the first electrode 190 and the second electrode 200 to be connected to external circuits at the same level, thereby improving yield and reliability.

As shown in FIG. 1B, the optoelectronic semiconductor device 10 further includes a first conductive layer 160 and a second conductive layer 180. The first conductive layer 160 locates in the first opening 210. The first conductive layer 160 directly contacts and electrically connects to the first semiconductor layer 110. The second conductive layer 180 locates in the second opening 220. The second conductive layer 180 directly contacts and electrically connects to the second semiconductor layer 130. The first conductive layer 160 may reduce the contact resistance between the first electrode 190 and the first semiconductor layer 110. The second conductive layer 180 may reduce the contact resistance between the second electrode 200 and the second semiconductor layer 130. Therefore, the operating voltage of the optoelectronic semiconductor device can be reduced. In some embodiments, the first conductive layer 160 and the second conductive layer 180 are spaced apart from the second insulating structure 150. In other words, the first conductive layer 160 and the second conductive layer 180 do not directly contact the second insulating structure 150. In other embodiments, the first conductive layer 160 and the second conductive layer 180 may directly contact the second insulating structure 150. In some embodiments, the first conductive layer 160 and the second conductive layer 180 are not covered by the second insulating structure 150.

In some embodiments, the second insulating structure 150 includes a second thickness W2 larger than the first thickness W1. For example, a ratio of the second thickness W2 to the first thickness W1 is larger than 1 and smaller than or equal to 5, which means 1<W2/W1≤5. In one embodiment, the first thickness W1 is between 50 nm and 150 nm, and the second thickness W2 is between 200 nm and 800 nm.

In some embodiments, the first conductive layer 160 and the second conductive layer 180 may each include metal material, alloy material, conductive oxide material. For example, the metal material may include chromium (Cr), titanium (Ti), germanium (Ge), beryllium (Be), zinc (Zn), gold (Au), silver (Ag), tin (Sn), nickel (Ni), or copper (Cu). The alloy material may include an alloy of at least two of the above metals, such as germanium-gold-nickel (Ge—Au—Ni), beryllium-gold (Be—Au), germanium-gold (Ge—Au), zinc-gold (Zn—Au), gold-tin (Au—Sn), or tin-silver-copper (Sn—Ag—Cu). The conductive oxide material may include indium tin oxide (ITO), indium oxide (InO), tin oxide (SnO), cadmium tin oxide (CTO), antimony tin oxide (ATO), aluminum zinc oxide (AZO), zinc tin oxide (ZTO), gallium zinc oxide (GZO), indium tungsten oxide (IWO), zinc oxide (ZnO) or indium zinc oxide (IZO). In an embodiment, the first conductive layer 160 and the second conductive layer 180 are Be—Au alloy and GeAu alloy, respectively.

The first opening 210 and the second opening 220 may have the same or different shapes, and the first conductive layer 160 and the second conductive layer 180 may also have the same or different shapes, such as a circle, a rectangle, or another polygon. The shape of the first opening 210 and the shape of the first conductive layer 160 may be the same or different. The shape of the second opening 220 and the shape of the second conductive layer 180 may be the same or different. That is, the shape of the first opening 210 and the shape of the first conductive layer 160 may be configured conformally, and the shape of the second opening 220 and the shape of the second conductive layer 180 may be configured conformally.

According to some embodiments of the present disclosure, FIG. 1C illustrates a cross-sectional view of the optoelectronic semiconductor device 10 along line A-A′ shown in FIG. 1A. The structure shown in FIG. 1C is similar to the structure shown in FIG. 1B, except that the first insulating structure 140 may include a shape other than a rectangle, such as a triangle (for example, taper), another polygon, or a combination thereof. In other words, the first thickness of the first insulating structure 140 is not a constant value. The first thickness of the first insulating structure 140 may gradually increase or decrease along the direction from the stack structure toward the substrate 100.

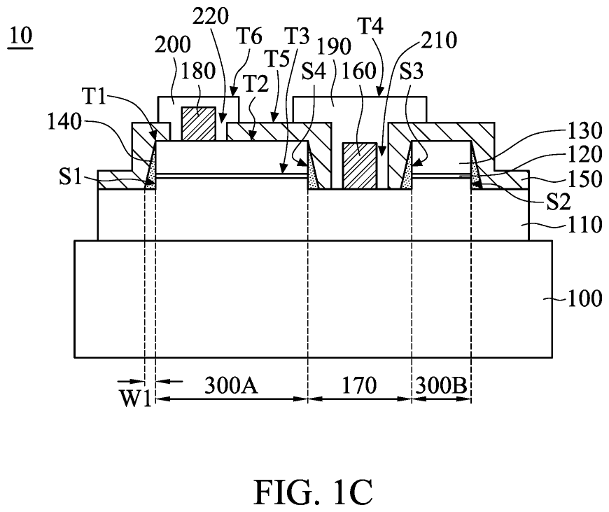

FIG. 2A illustrates a top view of an optoelectronic semiconductor device 20 according to other embodiments of the present disclosure. FIG. 2B illustrates a cross-sectional view of the optoelectronic semiconductor device 20 along line A-A′ shown in FIG. 2A. The optoelectronic semiconductor device 20 is similar to the optoelectronic semiconductor device 10 (as shown in FIGS. 1A to 1C), except that the first insulating structure 140 covers only the inner sidewalls S3 and S4 of the stack structure. The first insulating structure 140 does not cover the outer sidewalls S1 and S2 of the stack structure. In the embodiment shown in FIG. 2B, although the shape of the first insulating structure 140 is shown as a triangle (for example, taper), the shape of the first insulating structure 140 may include a rectangle, another polygon, or combinations thereof.

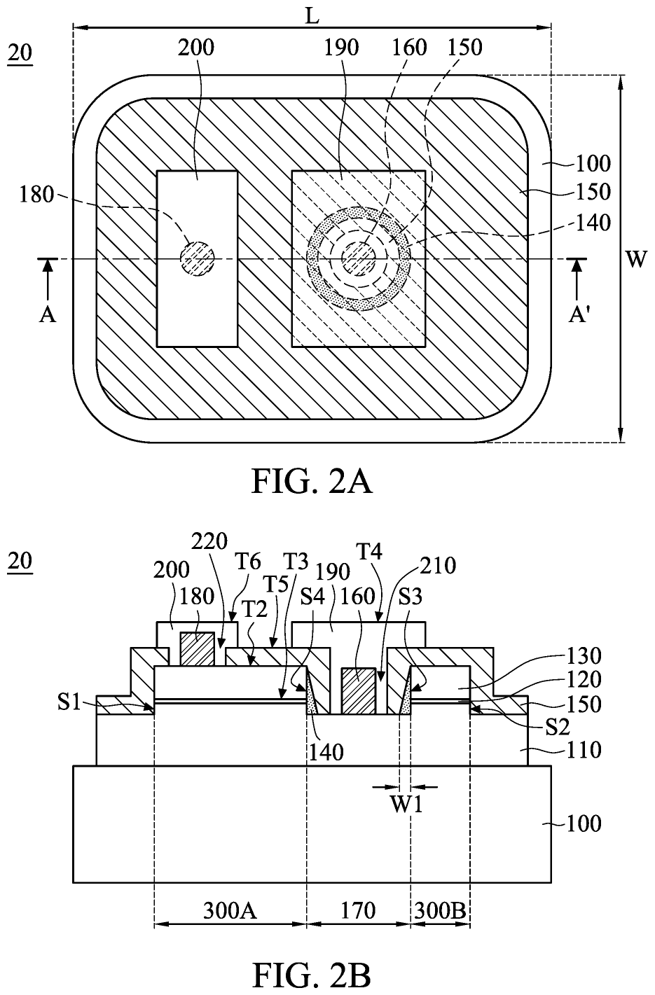

FIG. 3 illustrates a cross-sectional view of an optoelectronic semiconductor device 30 according to other embodiments of the present disclosure. The optoelectronic semiconductor device 30 is similar to the optoelectronic semiconductor device 10 as shown in FIGS. 1A to 1C, except that the first insulating structure 140 is only disposed on the outer sidewall S1 and the inner sidewall S4 of the stack structure. The first insulating structure 140 is not disposed on the outer sidewall S2 and inner sidewall S3 of the stack structure. In the embodiment shown in FIG. 3, although the shape of the first insulating structure 140 is shown as a triangle (for example, taper), the shape of the first insulating structure 140 may include a rectangle, another polygon, or combinations thereof.

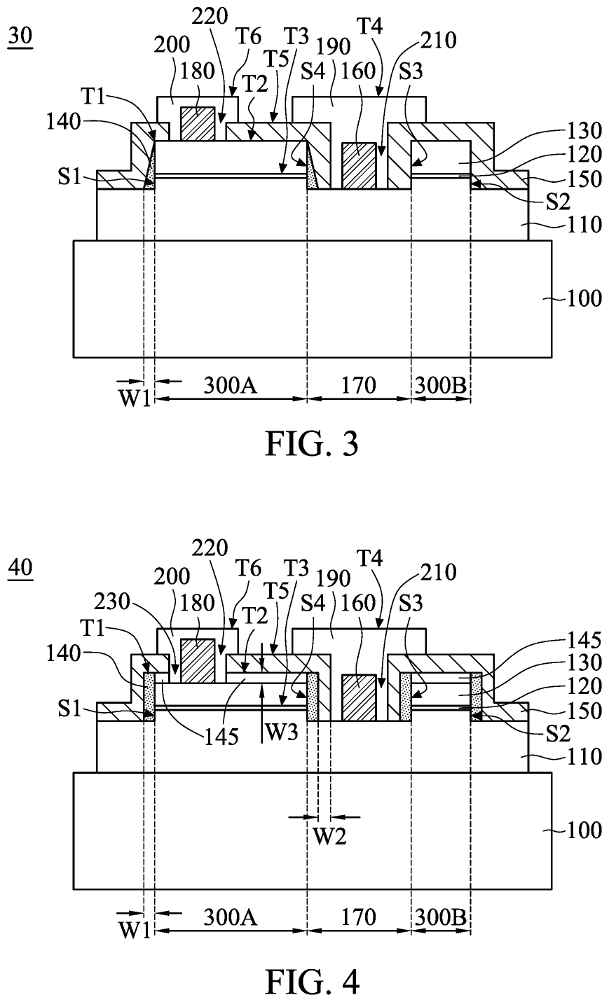

FIG. 4 illustrates a cross-sectional view of an optoelectronic semiconductor device 40 according to other embodiments of the present disclosure. The optoelectronic semiconductor device 40 is similar to the optoelectronic semiconductor device 10 as shown in FIGS. 1A to 1C, except that the stack structure may further include a passivation layer 145 disposed on the second semiconductor layer 130 and surrounding the recess 170. The first upper surface T1 of the first insulating structure 140 is coplanar with or lower than the top surface T2 of the stack structure. The first upper surface T1 of the first insulating structure 140 is higher than the second upper surface T3 of the active region 120. The second insulating structure 150 covers the first upper surface T1 of the first insulating structure 140, the sidewall of the first insulating structure 140, and the top surface T2 of the stack structure. The passivation layer 145 connects to the first insulating structure 140 and locates between the second semiconductor layer 130 and the second insulating structure 150. In some embodiment, the top surface T2 of the stack structure is the top surface of the passivation layer 145.

The passivation layer 145 includes a third opening 230 on the second semiconductor layer 130, and the third opening 230 overlaps with the second opening 220 in the vertical direction. In this way, the second conductive layer 180 is located in the second opening 220 and the third opening 230, and the second electrode 200 fills in the second opening 220 and the third opening 230. The third opening 230 and the second opening 220 may have the same or different shapes, such as a circle, a rectangle, or another polygon. The shape of the third opening 230 may be the same as or different from that of the second conductive layer 180. That is, the shape of the third opening 230 and the shape of the second conductive layer 180 may be configured conformally.

The passivation layer 145 includes a third thickness W3 smaller than the second thickness W2 of the second insulating structure 150. In some embodiment, the third thickness W3 is substantially equal to or smaller than the first thickness W1. In another embodiment, the third thickness W3 is larger than the first thickness W1.

In some embodiments, the material of the passivation layer 145 and the material of the first insulating structure 140 may be the same or different. The passivation layer 145 may include an oxide insulating material, a non-oxide insulating material, or a combination thereof. For example, the oxide insulating material may include silicon oxide (SiOₓ), titanium oxide (TiOₓ), aluminum oxide (Al₂O₃), tantalum oxide (Ta₂O₅). The non-oxide insulating material may include silicon nitride (SiNₓ), benzocyclobutene (BCB), cycloolefin copolymer (COC), fluorocarbon polymer, calcium fluoride (CaF₂) or magnesium fluoride (MgF₂).

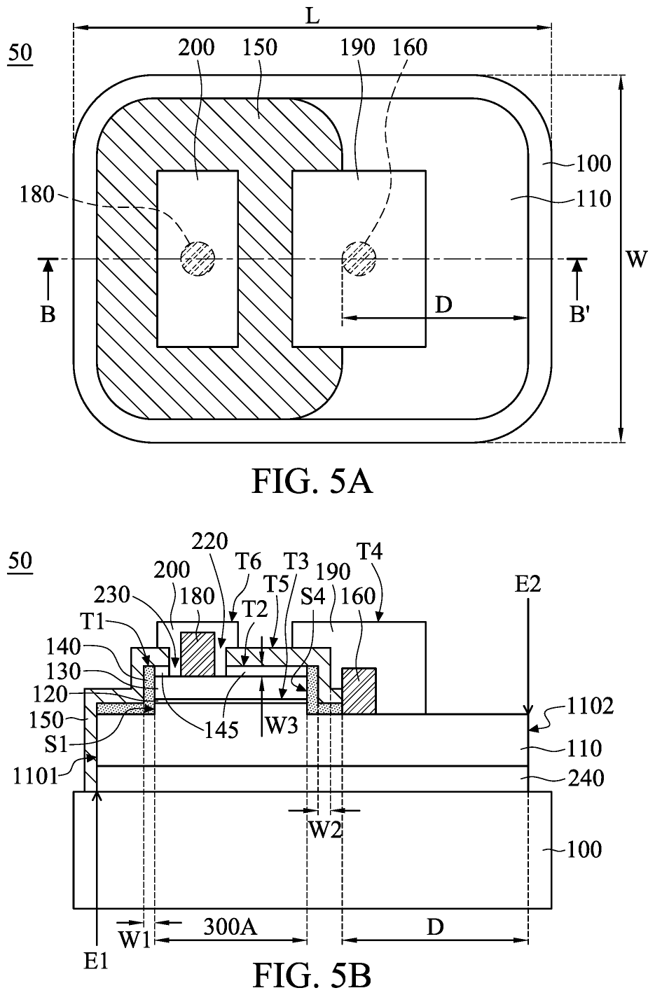

FIG. 5A illustrates a top view of an optoelectronic semiconductor device 50 according to other embodiments of the present disclosure. FIG. 5B illustrates a cross-sectional view of the optoelectronic semiconductor device 50 along line B-B′ shown in FIG. 5A. The optoelectronic semiconductor device 50 is similar to the optoelectronic semiconductor device 10 as shown in FIGS. 1A to 1C, except that the optoelectronic semiconductor device 50 does not include the mesa portion 300B as shown in FIG. 1B. In this embodiment, a portion of the surface of the first semiconductor layer 110 close to the first conductive layer 160 is not covered by the first insulating structure 140 and the second insulating structure 150. This configuration facilitates subsequent lithography and etching processes.

The first semiconductor layer 110 includes a first edge E1 and a second edge E2 opposite to the first edge E1 as shown in FIG. 5B. The first insulating structure 140 on the outer sidewall S1 of the mesa portion 300A further extends laterally to the edge E1 of the first semiconductor layer 110. In other words, the first insulating structure 140 covers the upper surface of the first semiconductor layer 110, and the second insulating structure 150 covers the first insulating structure 140. The second insulating structure 150 is not in direct contact with the upper surface of the first semiconductor layer 110. The first insulating structure 140 on the inner sidewall S4 extends laterally to one side of the first conductive layer 160. In other words, the first insulating structure 140 covers the upper surface of the first semiconductor layer 110 between the first conductive layer 160 and the inner sidewall S4, and the second insulating structure 150 covers the first insulating structure 140. In the embodiment, from a cross sectional view of the optoelectronic semiconductor device 50, the first semiconductor layer 110 has a first side surface 1101 close to the first edge E1 and a second side surface 1102 close to the second edge E2. The second insulating structure 150 covers the first side surface 1101 without covering the second side surface 1102.

As shown in FIG. 5B, there is a distance D between the edge E2 of the first semiconductor layer 110 close to the first conductive layer 160 and the first insulating structure 140 or the second insulating structure 150. In some embodiments, the distance D may be 2 μm to 20 μm, such as 4 μm to 10 μm. In an embodiment, a bonding material 240 may be disposed between the stack structure and the substrate 100 to enhance the bonding strength. The bonding material 240 may be a light-transmitting material (for example, benzocyclobutene (BCB), polyimide (PI), silicon oxide (SiO₂), titanium oxide (TiO₂), tantalum oxide (Ta₂O₅), aluminum oxide (Al₂O₃) or silicon nitride (SiₓN_{y})). In this embodiment, the second insulating structure 150 further extends to cover the sidewall of the first insulating structure 140, the sidewall of the first semiconductor layer 110, and the sidewall of the bonding material 240. The second insulating structure 150 contacts the substrate 100, while the first insulating structure 140 does not contact the substrate 100.

To sum up, in some embodiments of the present disclosure, the insulating structure may be disposed on entire or a portion of the sidewall of the stack structure. In this way, the reverse voltage of optoelectronic semiconductor device can be increased, and the failure caused by leakage of the optoelectronic semiconductor device can be avoided, thereby improving the reliability and yield of optoelectronic semiconductor device.

The foregoing has outlined features of several embodiments such that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

What is claimed is:

1. An optoelectronic semiconductor device, comprising:
a stack structure having a top surface and comprising a first semiconductor layer, a second semiconductor layer and an active region between the first semiconductor layer and the second semiconductor layer;
a first insulating structure covering the stack structure and having a first upper surface and a sidewall, wherein the first upper surface is coplanar with or lower than the top surface of the stack structure; and
a second insulating structure covering the first upper surface, the sidewall of the first insulating structure and the top surface of the stack structure, wherein the first insulating structure directly contacts the second insulating structure.

2. The optoelectronic semiconductor device of claim 1, wherein the active region has a second upper surface, wherein the first upper surface of the first insulating structure is higher than the second upper surface of the active region.

3. The optoelectronic semiconductor device of claim 1, wherein the stack structure comprises a mesa portion and a recess, wherein the mesa portion comprises an inner sidewall and an outer sidewall, wherein the outer sidewall surrounds the inner sidewall, and the inner sidewall defines the recess.

4. The optoelectronic semiconductor device of claim 3, wherein the first insulating structure covers the outer sidewall and/or the inner sidewall of the mesa portion.

5. The optoelectronic semiconductor device of claim 3, wherein the first insulating structure does not cover the outer sidewall or the inner sidewall of the mesa portion.

6. The optoelectronic semiconductor device of claim 3, wherein the second insulating structure comprises:
a first opening on the first semiconductor layer, wherein the first opening overlaps the recess in a vertical direction; and
a second opening on the second semiconductor layer, wherein the second opening overlaps the mesa portion in the vertical direction, and the second opening and the first opening are separated from each other.

7. The optoelectronic semiconductor device of claim 1, further comprising a first conductive layer on the first semiconductor layer.

8. The optoelectronic semiconductor device of claim 1, further comprising a second conductive layer on the second semiconductor layer.

9. The optoelectronic semiconductor device of claim 1, further comprising:
a first electrode on the first semiconductor layer and comprising a third upper surface; and
a second electrode on the second semiconductor layer;
wherein the second insulating structure comprises a fourth upper surface and the second electrode comprises a fifth upper surface, wherein the third upper surface of the first electrode is higher than the fourth upper surface of the second insulating structure, and the fifth upper surface of the second electrode is higher than the fourth upper surface of the second insulating structure.

10. The optoelectronic semiconductor device of claim 3, further comprising a passivation layer on the second semiconductor layer.

11. The optoelectronic semiconductor device of claim 10, wherein the passivation layer surrounds the recess.

12. The optoelectronic semiconductor device of claim 10, wherein the passivation layer connects to the first insulating structure and locates between the second semiconductor layer and the second insulating structure.

13. The optoelectronic semiconductor device of claim 1, wherein the first insulating structure comprises a first thickness and the second insulating structure comprises a second thickness larger than the first thickness.

14. The optoelectronic semiconductor device of claim 13, wherein a ratio of the second thickness to the first thickness is larger than 1 and smaller than or equal to 5.

15. The optoelectronic semiconductor device of claim 13, wherein the first thickness is between 50 nm and 150 nm, and the second thickness is between 200 nm and 800 nm.

16. The optoelectronic semiconductor device of claim 1, further comprising a passivation layer on the second semiconductor layer, and wherein the first insulating structure comprises a first thickness, the second insulating structure comprises a second thickness and the passivation layer comprises a third thickness smaller than or equal to the first thickness.

17. The optoelectronic semiconductor device of claim 16, wherein the third thickness is smaller than the second thickness.

18. The optoelectronic semiconductor device of claim 1, further comprising a passivation layer on the second semiconductor layer, and wherein the material of the passivation layer and the material of the first insulating structure are the same.

19. The optoelectronic semiconductor device of claim 1, wherein the first semiconductor layer has a first side surface and a second side surface, and the second insulating structure covering the first side surface without covering the second side surface.

20. The optoelectronic semiconductor device of claim 1, further comprising a substrate, and the second insulating structure contacts the substrate.
